(19) United States
(12) Patent Application Publication
(10) Pub. No.: US 2025/0234485 A1
(43) Pub. Date: Jul. 17, 2025

(54) MANIFOLD LIQUID DRAINAGE SYSTEM

(71) Applicant: Auras Technology Co., Ltd., New Taipei City (TW)

(72) Inventors: Yi-Le CHENG, New Taipei City (TW); Chien-Yu CHEN, New Taipei City (TW); Chih-Wei CHEN, New Taipei City (TW); Tian-Li YE, New Taipei City (TW)

(21) Appl. No.: 18/795,622

(22) Filed: Aug. 6, 2024

Related U.S. Application Data
(60) Provisional application No. 63/620,018, filed on Jan. 11, 2024.

(30) Foreign Application Priority Data
Jun. 26, 2024 (TW) 113123669

(51) Int. Cl. H05K 7/20; F16K 31/02; F16L 37/107

(52) U.S. Cl. CPC H05K 7/20272; F16K 31/02; F16L 37/107

(57) ABSTRACT

A manifold liquid drainage system includes a first liquid drain body and a manifold assembly. The first liquid drain body includes a first hollow flow channel and a plurality of first openings. The manifold assembly is fixed to at least one of the first openings and communicates with the first hollow flow channel, wherein the manifold assembly includes a pipe, a quick release joint, an electronic flow valve, and a control circuit board. The pipe is connected to one of the openings. The electronic flow valve is installed between the pipe and the quick release joint. The control circuit board controls the electronic flow valve to regulate the liquid flow through the pipe.

### CROSS-REFERENCE TO RELATED APPLICATION

This application claims priority to Taiwan Application Serial Number 113123669, filed Jun. 26, 2024, and U.S. Provisional Application Ser. No. 63/620,018, filed Jan. 11, 2024, the disclosures of which are incorporated herein by reference in their entireties.

### BACKGROUND

### Field of Disclosure

The present disclosure relates to a manifold liquid drainage system, and more particularly to a manifold liquid drainage system in a cooling system.

### Description of Related Art

A computing server provides its powerful computing power through the network, allowing it to complete a large amount of work in a short period of time and provide services to a large number of users. Conventional servers are usually densely installed on racks that can be centrally installed in air-conditioned computer rooms.

As the computing power of servers continues to improve, computer rooms with only air conditioning can no longer meet the cooling needs of servers such that water-cooling heat dissipation systems are introduced into servers. In order to meet the needs of server modularization and quick disassembly, the water-cooling manifold liquid drainage system also needs to be improved at the same time to meet the needs of different loads and economical power consumption of individual servers.

### SUMMARY

The present disclosure provides an improved manifold liquid drainage system to deal with the needs of the prior art problems.

In one or more embodiments, a manifold liquid drainage system includes a first liquid drain body and a manifold assembly. The first liquid drain body includes a first hollow flow channel and a plurality of first openings. The manifold assembly is fixed to at least one of the first openings and fluidly-communicably connected to the first hollow flow channel, wherein the manifold assembly includes a pipe, a quick release joint, an electronic flow valve, and a control circuit board. The pipe is connected one of the first openings. The electronic flow valve is installed between the pipe and the quick release joint. The control circuit board controls the electronic flow valve to regulate the liquid flow through the pipe.

In one or more embodiments, the manifold assembly further includes a sensing device installed on one side of the pipe.

In one or more embodiments, the sensing device is configured to monitor changes of the liquid flow in the pipe and generate a sensing signal, wherein the control circuit board is configured to receive the sensing signal and control the electronic flow valve to regulate the liquid flow through the pipe based on the sensing signal.

In one or more embodiments, the sensing device further includes a liquid sensor installed on a first side of the pipe.

In one or more embodiments, the liquid sensor is a pressure sensor or flow rate sensor.

In one or more embodiments, the liquid sensor is configured to sense a pressure or a flow rate of the liquid flow in the pipe, the control circuit board is configured to close the electronic flow valve corresponding to a sudden change when the liquid sensor senses the sudden change in the pressure or the flow rate.

In one or more embodiments, the liquid sensor is configured to sense a pressure or a flow rate of the liquid flow in the pipe, the control circuit board is configured to control the corresponding electronic flow valve based on a relationship between a current reading of the pressure or the flow rate of the liquid sensor and an average reading of the pressure or the flow rate of the liquid sensor.

In one or more embodiments, the sensing device further includes a temperature sensor installed on a second side of the pipe, the first side and the second side are two opposite sides of the pipe.

In one or more embodiments, the temperature sensor is configured to sense a temperature reading of the liquid flow in the pipe, and the control circuit board is used to control the corresponding electronic flow valve based on a relationship between a current reading of the temperature of the liquid flow of the temperature sensor and a temperature predetermined value.

In one or more embodiments, the sensing device further includes a liquid leakage detector disposed on the pipe.

In one or more embodiments, the liquid leakage detector is a resistor or a capacitor.

In one or more embodiments, the control circuit board is configured to close the electronic flow valve corresponding to a water leakage condition when the leakage detector detects the water leakage condition.

In one or more embodiments, the control circuit board is electrically connected to the electronic flow valve and the sensing device.

In one or more embodiments, the manifold liquid drainage system further includes a second liquid drain body, wherein the first liquid drain body and the second liquid drain body are arranged vertically in parallel.

In one or more embodiments, the second liquid drain body includes a second hollow flow channel and a plurality of second openings.

In one or more embodiments, the manifold assembly is fixed to at least one of the second openings and fluidly-communicably connected to the second hollow flow channel.

In one or more embodiments, the manifold liquid drainage system further comprising a plurality of devices to be cooled, each device to be cooled includes a cooling flow channel, the cooling flow channel is fluidly-communicably connected to the manifold assembly on the first liquid drain body and the second liquid drain body.

In sum, the manifold liquid drainage system disclosed herein is equipped with a liquid sensor, a temperature sensor and a liquid leakage detector in the manifold assembly of each opening, and the control circuit board is utilized to receive the sensing signals of the liquid sensor and the temperature sensor to control the electronic flow valve, thereby adjusting the flow rate of individual manifold assemblies. The control circuit board also uses liquid sensor and/or liquid leakage detector to detect water leakage to prevent water leakage from damaging the corresponding devices to be cooled.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 illustrates a diagram of a manifold liquid drainage system according to an embodiment of the present disclosure;

FIG. 2 illustrates a perspective view of a liquid drainage device of a manifold liquid drainage system according to an embodiment of the present disclosure;

FIG. 3 illustrates an enlarged view of a top portion of the liquid drainage device in FIG. 2;

FIG. 4 illustrates an enlarged view of a single manifold assembly of the liquid drainage device in FIG. 2;

FIG. 5 illustrates an operation method of a manifold liquid drainage system according to a first embodiment of the present invention;

FIG. 6 illustrates an operation method of a manifold liquid drainage system according to a second embodiment of the present invention; and

FIG. 7 illustrates an operation method of a manifold liquid drainage system according to a third embodiment of the present invention.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

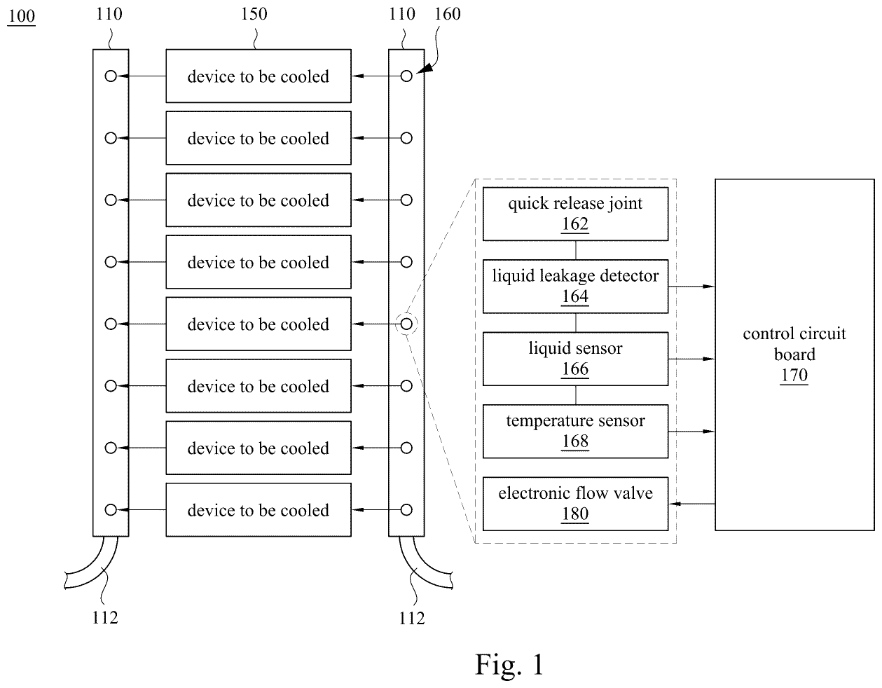

Reference is made to FIG. 1, which illustrates a diagram of a manifold liquid drainage system according to an embodiment of the present disclosure. The manifold liquid drainage system 100 includes two parallel liquid drainage devices 110, and a plurality of devices to be cooled 150 are connected between the two liquid drainage devices 110. Each liquid drainage device 110 is equipped with a plurality of manifold assemblies 160. Each manifold assembly 160 includes a quick release joint 162, an electronic flow valve 180, a liquid sensor 166, a temperature sensor 168 and other components, and a control circuit board 170 is used to control the flow of all manifold assemblies 160 as required. For example, the manifold liquid drainage system 100 utilizes the control circuit board 170 to receive sensing signals from the liquid sensor 166 and the temperature sensor 168 to control the electronic flow valve 180 to adjust or regulate the liquid flow through individual manifold assemblies 160. The liquid sensor 166 may be a pressure sensor or a flow rate sensor, which is used to monitor the pressure or flow rate of the liquid in the manifold assembly 160. If the pressure or flow rate exceeds a preset range, the liquid sensor 166 will send corresponding sensing signals (such as pressure or flow rate) to the control circuit board 170. The temperature sensor 168 monitors the temperature of the liquid in manifold assembly 160. Similarly, if the temperature exceeds a preset range, the temperature sensor 168 will also send a sensing signal (such as a temperature value) to the control circuit board 170. The control circuit board 170 will calculate the flow signal based on the received sensing signal (such as pressure and temperature) and send it to the corresponding electronic flow valve 180. The electronic flow valve 180 adjusts the flow rate of the manifold assembly 160 according to the received sensing signal to maintain it within the set pressure and temperature range. The manifold liquid drainage system 100 ensures that each manifold assembly 160 can operate under optimal working conditions by continuously monitoring the pressure, flow rate or temperature of the liquid flow and adjusting the flow rate according to actual conditions.

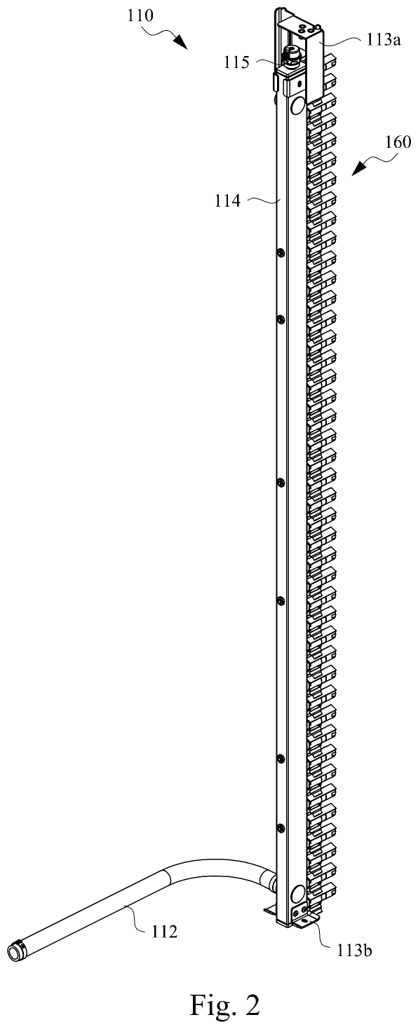

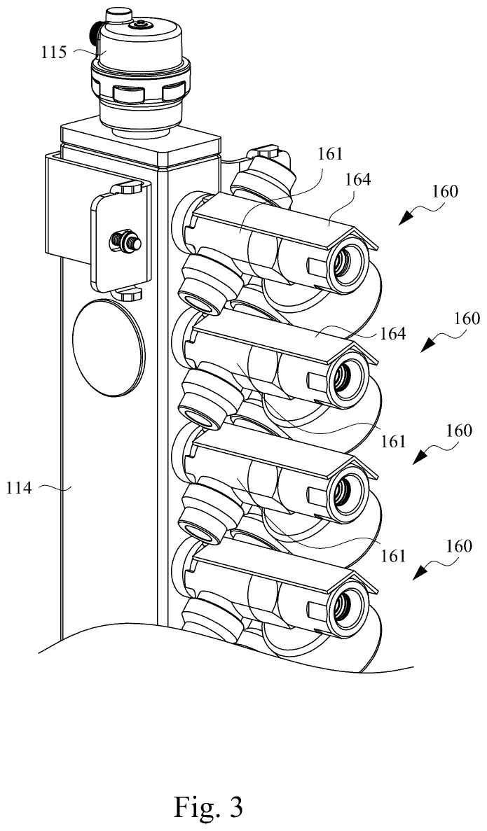

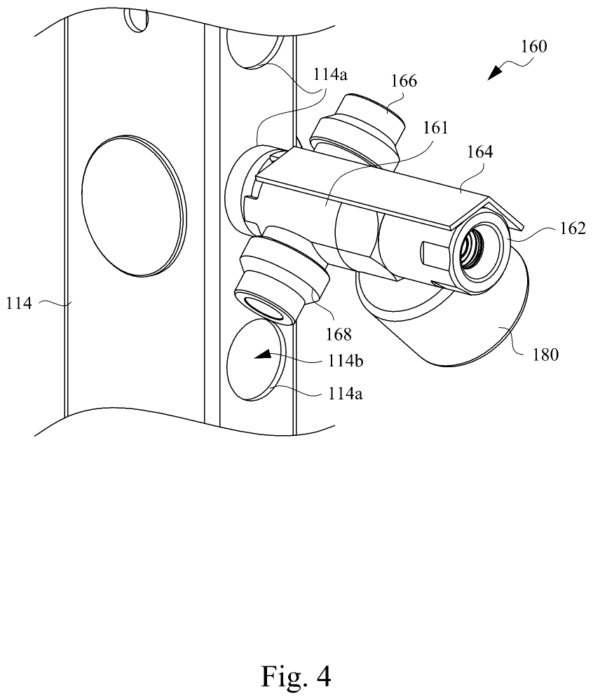

Reference is made to FIGS. 2, 3 and 4, FIG. 2 illustrates a perspective view of a liquid drainage device 110 of a manifold liquid drainage system 100 according to an embodiment of the present disclosure, FIG. 3 illustrates an enlarged view of a top portion of the liquid drainage device 110 in FIG. 2 with the locking frame 113a removed, and FIG. 4 illustrates an enlarged view of a top portion of the liquid drainage device 110 in FIG. 2. The liquid drainage device 110 includes a liquid drain body 114. The liquid drain body 114 includes a hollow flow channel 114b and a plurality of openings 114a. Each opening 114a is equipped with a manifold assembly 160 to adjust the flow rate through the individual opening 114a according to actual conditions. Each manifold assembly 160 is fluidly-communicably connected to the hollow flow channel 114b through the corresponding opening 114a.

In some embodiments of the present invention, two liquid drainage devices 110 are arranged vertically in parallel to form a configuration as shown in FIG. 1, i.e., two liquid drain bodies 114 are arranged vertically in parallel.

In some embodiments of the present invention, the top and bottom ends of the liquid drainage device 110 include a locking frame (113a, 113b) respectively, thereby firmly locking the liquid drain body 114.

In some embodiments of the present invention, the liquid drainage device 110 includes an exhaust valve 115. The exhaust valve 115 is located at the top of the liquid drain body 114 and fluidly-communicably connected to the hollow flow channel 114b. The main function of the exhaust valve 115 is to remove air or bubbles from the system. Air may be present in the manifold liquid drainage system 100, which may affect cooling efficiency and cause system instability. The exhaust valve 115 can discharge air or bubbles from the system to ensure that the coolant can be effectively flown to the entire system, thereby improving the cooling efficiency and performance of the system.

In some embodiments of the present invention, the liquid drainage device 110 includes an inlet and outlet pipe 112. The inlet and outlet pipe 112 is fluidly-communicably connected to the hollow flow channel 114b of the liquid drain body 114. The inlet and outlet pipe 112 can serve as a liquid inlet or liquid outlet of the liquid drainage device 110. When the inlet and outlet pipe 112 serves as the liquid inlet, the liquid is input into the liquid drain body 114 from the inlet and outlet pipe 112, and is output from the liquid drain body 114 through a plurality of manifold assemblies 160. When the inlet and outlet pipe 112 serve as the liquid outlet, liquid is input into the liquid drain body 114 from the plurality of manifold assemblies 160, and is output from the liquid drain body 114 through the inlet and outlet pipe 112.

In some embodiments of the present invention, each manifold assembly 160 includes a pipe 161, a quick release joint 162, a liquid leakage detector 164, an electronic flow valve 180, a liquid sensor 166, a temperature sensor 168 and other components. The pipe 161 is assembled on a plurality of openings 114a of the liquid drain body 114, and is fluidly-communicably connected to the hollow flow channel 114b. The quick release joint 162 is used to provide pipe connection for the cooling flow channel of devices to be cooled 150. The cooling flow channel of devices to be cooled 150 is fluidly-communicably connected to the manifold assembly of two liquid drain bodies 114. The electronic flow valve 180 is installed between the pipe 161 and the quick release joint 162. The electronic flow valve 180 is used to regulate the liquid flow through pipes 161 and openings 114a. The liquid sensor 166 is installed on the first side of the pipe 161, and the temperature sensor 168 is installed on the second side of the pipe 161. The first side and the second side are two opposite sides of the pipe 161. The liquid leakage detector 164 is located on the pipe 161 and is used to detect whether the pipe 161 and/or the quick release joint 162 are liquid-leaking.

In some embodiments of the present invention, the liquid leakage detector 164 can be a resistor or a capacitor. When a resistor is used as the liquid leakage detector, water leakage is usually detected based on the conductivity of the liquid. When the liquid touches the resistor, it causes the resistance value to change, triggering an alarm. When a capacitor is used as the liquid leakage detector, the presence of liquid is detected by measuring the capacitance change of the capacitor. When the liquid triggers the capacitor, it changes its capacitance value, triggering an alarm. Both methods are effective in detecting water leaks, and the choice depends on the requirements and performance of the specific application.

In some embodiments of the present invention, the liquid leakage detector 164 is arranged between two adjacent pipes 161 to detect whether the upper one of the two adjacent pipes 161 is liquid-leaking when the liquid drain body 114 is arranged vertically.

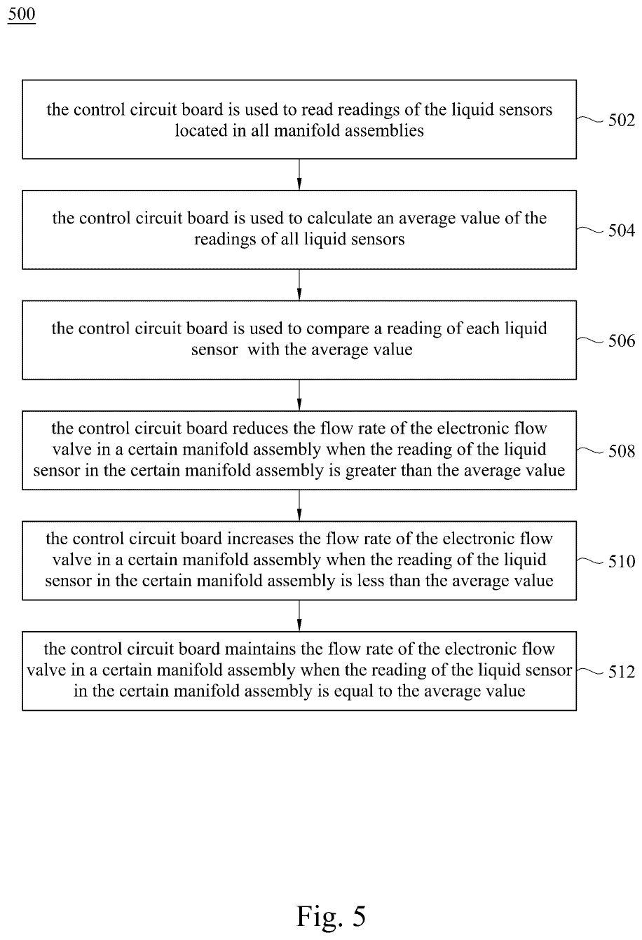

Reference is made to FIG. 5, which illustrates an operation method 500 of a manifold liquid drainage system according to a first embodiment of the present invention. The method 500 is an operation method of the manifold liquid drainage system in response to the readings of the liquid sensor.

In step 502 of the method 500, the control circuit board 170 is used to read pressure or flow rate readings of the liquid sensors 166 located in all manifold assemblies 160. The liquid sensor 166 is used to sense the liquid pressure or flow reading through the pipe 161. The manifold assembly 160 in the first embodiment can be installed on the openings of the liquid drainage device 110 upstream or downstream of the devices to be cooled 150.

In step 504 of the method 500, the control circuit board 170 is used to calculate an average value of the pressure or flow rate readings of all liquid sensors 166.

In step 506 of the method 500, the control circuit board 170 is used to compare the pressure or flow rate reading of each liquid sensor 166 with the average value calculated in step 504.

In step 508 of the method 500, the control circuit board 170 reduces the flow rate of the electronic flow valve 180 in a certain manifold assembly 160 when the pressure or flow rate reading of the liquid sensor 166 in the certain manifold assembly 160 is greater than the average value.

In step 510 of the method 500, the control circuit board 170 increases the flow rate of the electronic flow valve 180 in a certain manifold assembly 160 when the pressure or flow rate reading of the liquid sensor 166 in the certain manifold assembly 160 is less than the average value.

In step 512 of the method 500, the control circuit board 170 maintains the flow rate of the electronic flow valve 180 in a certain manifold assembly 160 when the pressure or flow rate reading of the liquid sensor 166 in the certain manifold assembly 160 is equal to the average value.

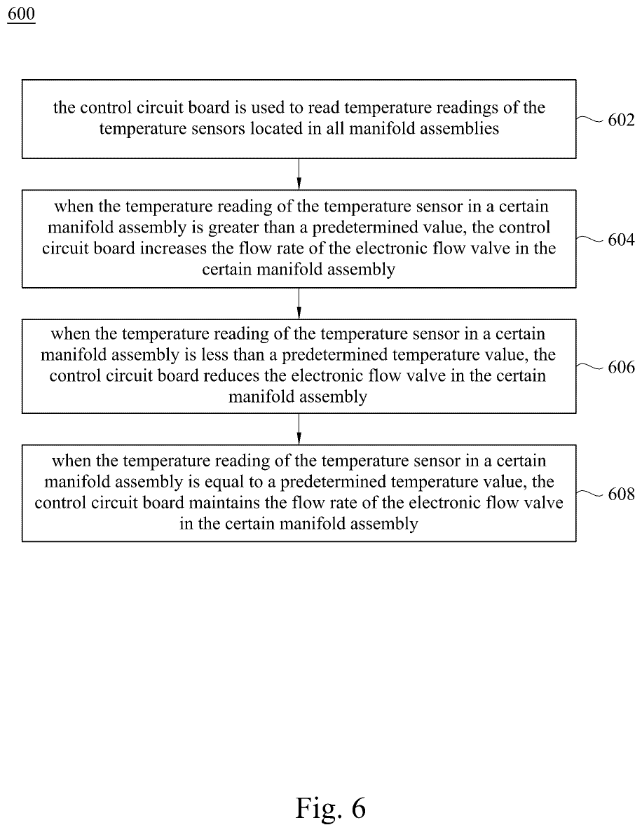

Reference is made to FIG. 6, which illustrates an operation method 600 of a manifold liquid drainage system according to a second embodiment of the present invention. The method 600 is an operation method 600 of a manifold liquid drainage system in response to readings from a temperature sensor.

In step 602 of the method 600, the control circuit board 170 is used to read temperature readings of the temperature sensors 168 located in all manifold assemblies 160. The manifold assembly 160 in the second embodiment is installed on the openings of the liquid drainage device 110 downstream of the devices to be cooled 150.

In step 604 of the method 600, when the temperature reading of the temperature sensor 168 in a certain manifold assembly 160 is greater than a predetermined value, the control circuit board 170 increases the flow rate of the electronic flow valve 180 in the manifold assembly 160 and corresponding to the manifold assembly 160. Because the temperature reading of the temperature sensor 168 located downstream of a certain device to be cooled 150 is too high, the flow rate of the electronic flow valve 180 upstream or downstream of the devices to be cooled 150 is increased to reduce the operating temperature of the device to be cooled 150.

In step 606 of the method 600, when the temperature reading of the temperature sensor 168 in a certain manifold assembly 160 is less than a predetermined temperature value, the control circuit board 170 reduces the flow rate of the electronic flow valve 180 in the manifold assembly 160 and corresponding to the manifold assembly 160. Because the temperature reading of the temperature sensor 168 located downstream of a certain devices to be cooled 150 is less than the predetermined value, the flow rate of the electronic flow valve 180 upstream or downstream of the device to be cooled 150 is reduced to save electricity.

In step 608 of the method 600, when the temperature reading of the temperature sensor 168 in a certain manifold assembly 160 is equal to a predetermined temperature value, the control circuit board 170 maintains the flow rate of the electronic flow valve 180 in the manifold assembly 160 and corresponding to the manifold assembly 160.

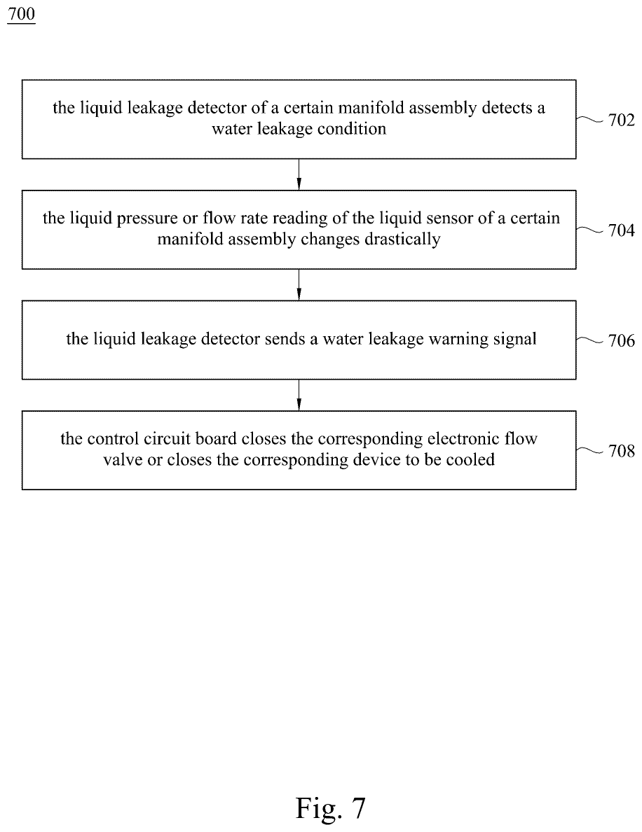

Reference is made to FIG. 7, which illustrates an operation method 700 of a manifold liquid drainage system according to a third embodiment of the present invention. The method 700 is an operation method of a manifold liquid drainage system in response to the risk of leakage.

In step 702 of the method 700, the liquid leakage detector 164 of a certain manifold assembly 160 detects a water leakage condition.

In step 704 of the method 700, the liquid pressure or flow rate reading of the liquid sensor 166 of a certain manifold assembly 160 shows a sudden change, indicating a serious water leakage condition.

In step 706 of the method 700, the liquid leakage detector 164 sends a water leakage warning signal to the control circuit board 170.

In step 708 of the method 700, the control circuit board 170 closes the corresponding electronic flow valve 180 or closes the corresponding device to be cooled 150.

In sum, the manifold liquid drainage system disclosed herein is equipped with a liquid sensor, a temperature sensor and a liquid leakage detector in the manifold assembly of each opening, and the control circuit board is utilized to receive the sensing signals of the liquid sensor and the temperature sensor to control the electronic flow valve, thereby adjusting the flow rate of individual manifold assemblies. The control circuit board also uses liquid sensor and/or liquid leakage detector to detect water leakage to prevent water leakage from damaging the corresponding devices to be cooled.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A manifold liquid drainage system comprising:
a first liquid drain body comprising a first hollow flow channel and a plurality of first openings; and
a manifold assembly fixed to at least one of the first openings and fluidly-communicably connected to the first hollow flow channel, wherein the manifold assembly comprises:
a pipe connected to one of the first openings;
a quick release joint;
an electronic flow valve installed between the pipe and the quick release joint; and
a control circuit board configured to control the electronic flow valve to regulate a liquid flow through the pipe.

2. The manifold liquid drainage system of claim 1, wherein the manifold assembly further comprises a sensing device installed on one side of the pipe.

3. The manifold liquid drainage system of claim 2, wherein the sensing device is configured to monitor changes of the liquid flow in the pipe and generate a sensing signal, wherein the control circuit board is configured to receive the sensing signal and control the electronic flow valve to regulate the liquid flow through the pipe based on the sensing signal.

4. The manifold liquid drainage system of claim 2, wherein the sensing device further comprises a liquid sensor installed on a first side of the pipe.

5. The manifold liquid drainage system of claim 4, wherein the liquid sensor is a pressure sensor or flow rate sensor.

6. The manifold liquid drainage system of claim 4, wherein the liquid sensor is configured to sense a pressure or a flow rate of the liquid flow in the pipe, the control circuit board is configured to close the electronic flow valve corresponding to a sudden change when the liquid sensor senses the sudden change in the pressure or the flow rate.

7. The manifold liquid drainage system of claim 4, wherein the liquid sensor is configured to sense a pressure or a flow rate of the liquid flow in the pipe, the control circuit board is configured to control a flow rate of the corresponding electronic flow valve based on a relationship between a current reading of the pressure or the flow rate of the liquid sensor and an average reading of the pressure or the flow rate of the liquid sensor.

8. The manifold liquid drainage system of claim 4, wherein the sensing device further comprises a temperature sensor installed on a second side of the pipe, the first side and the second side are two opposite sides of the pipe.

9. The manifold liquid drainage system of claim 8, wherein the temperature sensor is configured to sense a temperature reading of the liquid flow in the pipe, and the control circuit board is used to control a flow rate of the corresponding electronic flow valve based on a relationship between a current reading of the temperature of the liquid flow of the temperature sensor and a temperature predetermined value.

10. The manifold liquid drainage system of claim 2, wherein the sensing device further comprises a liquid leakage detector disposed on the pipe.

11. The manifold liquid drainage system of claim 10, wherein the liquid leakage detector is a resistor or a capacitor.

12. The manifold liquid drainage system of claim 10, wherein the control circuit board is configured to close the electronic flow valve corresponding to a water leakage condition when the liquid leakage detector detects the water leakage condition.

13. The manifold liquid drainage system of claim 2, wherein the control circuit board is electrically connected to the electronic flow valve and the sensing device.

14. The manifold liquid drainage system of claim 1 further comprising a second liquid drain body, wherein the first liquid drain body and the second liquid drain body are arranged vertically in parallel.

15. The manifold liquid drainage system of claim 14, wherein the second liquid drain body comprises a second hollow flow channel and a plurality of second openings.

16. The manifold liquid drainage system of claim 15, wherein the manifold assembly is fixed to at least one of the second openings and fluidly-communicably connected to the second hollow flow channel.

17. The manifold liquid drainage system of claim 16 further comprising a plurality of devices to be cooled, each device to be cooled includes a cooling flow channel, the cooling flow channel is fluidly-communicably connected to the manifold assembly on the first liquid drain body and the second liquid drain body.

18. An operation method of a manifold liquid drainage system, wherein the operation method comprises:
providing a liquid drain body including a hollow flow channel and a plurality of openings, wherein a plurality of manifold assemblies fixed to all the openings respectively and fluidly-communicably connected to the hollow flow channel;
using a control circuit board to read pressure or flow rate readings of liquid sensors located in all the manifold assemblies;
using the control circuit board to calculate an average value of the pressure or flow rate readings of all the liquid sensors;
using the control circuit board to compare the pressure or flow rate reading of each liquid sensor with the average value; and
using the control circuit board to reduce a flow rate of an electronic flow valve in a first manifold assembly of the manifold assemblies when the pressure or flow rate reading of the liquid sensor in the first manifold assembly is greater than the average value.

19. The operation method of claim 18 further comprising:
using the control circuit board to increase a flow rate of an electronic flow valve in a second manifold assembly of the manifold assemblies when the pressure or flow rate reading of the liquid sensor in the second manifold assembly is less than the average value.

20. The operation method of claim 18 further comprising:
using the control circuit board to maintain a flow rate of an electronic flow valve in a third manifold assembly of the manifold assemblies when the pressure or flow rate reading of the liquid sensor in the third manifold assembly is equal to the average value.
